(19) United States
(12) Patent Application Publication
(10) Pub. No.: US 2014/0210549 A1
(43) Pub. Date: Jul. 31, 2014

(54) METHOD AND APPARATUS FOR USING A PROCESSOR CONTROLLED SWITCHER WITH A POWER AMPLIFIER

(71) Applicant: QUALCOMM INCORPORATED, San Diego, CA (US)

(72) Inventors: Daniel Fred Filipovic, Solana Beach, CA (US); Jifeng Geng, San Diego, CA (US)

(73) Assignee: QUALCOMM INCORPORATED, San Diego, CA (US)

(21) Appl. No.: 13/752,304

(22) Filed: Jan. 28, 2013

(51) Int. Cl. H03G 3/30

(52) U.S. Cl. CPC H03G 3/3042
USPC 330/127

(57) ABSTRACT

Aspects disclosed herein relate to using a processor controlled switcher architecture with a high-efficiency PA control. A wireless communications device may be include a processor, a power amplifier and a processor controller PA switcher. In an aspect, the processor may be a modem, a RF chip, etc. In one example, the PA switcher may be configured to receive a switcher control signal on the control line. In an aspect, the switcher control signal may be based on future characteristics of an input signal. The PA switcher may be further configured to select a voltage path from among a plurality of voltage paths based on the switcher control signal to provide a supply voltage to the lower pass filter associated with the PA.

### BACKGROUND

1. Field

The disclosed aspects relate generally to enabling communications using a power amplifier PA and specifically to methods and systems for using a processor controlled switcher architecture with a high-efficiency power amplifier.

2. Background

Current power amplifier (PA) control apparatuses and methods are generally configured to use one or more combination of four PA control schemes. First, a battery direct scheme directly connects the battery to the PA. This may be efficient at times when max power is needed, but at lower powers efficiency drops rapidly because it's not necessary to use full battery voltage. Second, an average power tracking (APT) scheme uses a third party switcher between the batter and PA and uses an algorithm to change voltage between power control groups. Compared to the battery direct scheme, at lower powers efficiency falls off more gradually since PA voltage is correspondingly decreased. Third, a super APT (SAPT) scheme uses an algorithm to change voltage per various power control groups and also uses predistortion and adaptiveness to squeeze voltage to limits. Fourth, envelope tracking (ET) uses a separate chipset to track the signal envelope at high speed and high precision. This scheme may require PAs optimized for ET usage and may require an ET digital to analog converter (DAC) on the mobile station modem (MSM).

As such, a system and apparatus that provides high-efficiency PA control without the limitations discussed above may be desired.

### SUMMARY

The following presents a simplified summary of one or more aspects in order to provide a basic understanding of such aspects. This summary is not an extensive overview of all contemplated aspects, and is intended to neither identify key or critical elements of all aspects nor delineate the scope of any or all aspects. Its sole purpose is to present some concepts of one or more aspects in a simplified form as a prelude to the more detailed description that is presented later.

Various aspects are described in connection with providing high-efficiency PA control. A wireless communications device may be include a processor, a power amplifier and a modem controller PA switcher. In one example, the PA switcher may be configured to receive a switcher control signal on the control line. In an aspect, the switcher control signal may be based on future characteristics of an input signal. The PA switcher may be further configured to select a voltage path from among a plurality of voltage paths based on the switcher control signal to provide a supply voltage to the lower pass filter associated with the PA.

According to related aspects, a method provides a mechanism for providing high-efficiency PA control. The method can include receiving, from a modem, a switcher control signal on a control line. Moreover, the method can include switching, by a PA switcher, between a voltage source path or a ground voltage path to provide a supply voltage to a power amplifier based on the received switcher control signal. In an aspect, the switch control signal may indicate which path to use based on one or more signal peaks in a future window at the modem.

Another aspect relates to a communications apparatus. The wireless communications apparatus can include means for receiving, from a modem, a switcher control signal on a control line. Moreover, the communications apparatus can include means for switching between a voltage source path or a ground voltage path to provide a supply voltage to a power amplifier based on the received switcher control signal. In an aspect, the switch control signal may indicate which path to use based on one or more signal peaks in a future window at the modem.

Another aspect relates to a communications apparatus. The apparatus can include a modem configured to predict a supply voltage value for a power amplifier based on a signal lower bound. Moreover, the apparatus may include a PA switcher including a control line coupled to a modem a first voltage path supplied by a voltage source, a second voltage path supplied by a ground voltage, and a output line coupled to a power amplifier voltage supply line. The PA switcher may be configured to switch between a voltage source path and a ground voltage path to provide a supply voltage to a power amplifier based on the received switcher control signal. In an aspect, the switch control signal may indicate which path to use based on one or more signal peaks in a future window at the modem.

Another aspect relates to a computer program product, which can have a computer-readable medium comprising code for receiving, from a modem, a switcher control signal on a control line. Moreover, the computer-readable medium can also include code for switching, by a PA switcher, between a voltage source path or a ground voltage path to provide a supply voltage to a power amplifier based on the received switcher control signal. In an aspect, the switch control signal may indicate which path to use based on one or more signal peaks in a future window at the modem.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

The disclosed aspects will hereinafter be described in conjunction with the appended drawings, provided to illustrate and not to limit the disclosed aspects, wherein like designations denote like elements, and in which:

FIG. 1 is a functional block diagram of an example transmitter including a modem and a power amplifier, according to an aspect;

FIG. 2 is an example schematic diagram of a processor controlled power amplifier switcher, according to an aspect;

FIG. 3 is a flowchart diagram describing an example for using a processor controlled switcher architecture with a high-efficiency power amplifier, according to an aspect;

FIG. 4 is a functional block diagram example architecture of a communications device, according to an aspect; and

FIG. 5 is a functional block diagram of an example communication system for using a processor controlled switcher architecture with a high-efficiency power amplifier, according to an aspect.

### DETAILED DESCRIPTION

Various aspects are now described with reference to the drawings. In the following description, for purposes of explanation, numerous specific details are set forth in order to provide a thorough understanding of one or more aspects. It may be evident, however, that such aspect(s) may be practiced without these specific details.

A transmitter including a modem, a PA, and a PA switcher, coupled to the modem and PA, is described herein. The PA switcher may be configured to receive, from the modem, a switcher control signal on a control line, and switch between a voltage source path and a ground voltage path to provide a supply voltage to the power amplifier. In an aspect, the switch control signal may indicate which path to use based on one or more signal peaks in a future window at the modem. The transmitter may be used for various electronic devices such as wireless communication devices, cellular phones, personal digital assistants (PDAs), handheld devices, wireless modems, laptop computers, cordless phones, Bluetooth devices, consumer electronic devices, etc. For clarity, the use of the transmitter in a wireless communication device is described below.

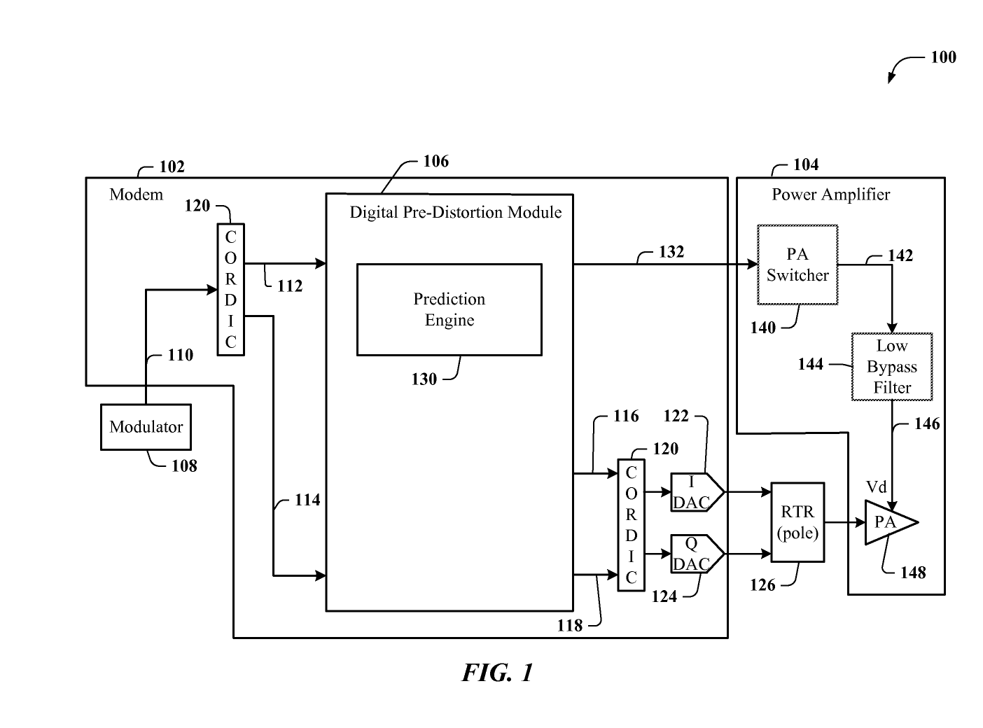

FIG. 1 illustrates a functional block diagram of an example transmitter 100 with modem 102 and PA component 104. Modem 102 may include a digital pre-distortion (DPD) module 106. In another aspect, DPD module 106 may be associated with another processor (e.g., RF chip, etc.), separate from modem 102. PA component 104 may include PA switcher 140 that is configured to provide a supply voltage 142 to low pass filer 144. Further, lower pass filter 144 is configured to provide a smoothed supply voltage 146 to PA 148.

Modem 102 may further include a coordinate rotation digital computer (CORDIC) component 120 that may be configured to receive an input signal 110 from a modulator 108 and divide the signal 110 into an amplitude component 112 and a phase component 114. DPD module 106 may process amplitude component 112 and phase component 114 to produce a pre-distorted amplitude component 116 and a pre-distorted phase component 118. The pre-distorted amplitude 116 and phase 118 components may be processed by CORDIC 120 and converted to amplitude and phase components of an analog signal using “I” digital to analog converter 122 (I DAC) and “Q” DAC 124, respectively. The analogs signal components may be combined through a radio transceiver (RTR) 126 and provided to PA 148.

Within DPD module 106, the amplitude component 112 may be processed using a prediction engine 130. In an aspect, prior to being received by prediction engine 130, a gain associated with the amplitude component 112 may be modified using a LUT (e.g., bLUT). Prediction engine 130 may then receive the modified amplitude component 112 and may determine an estimated voltage for input signal 110 and a control signal 132 for PA switcher 140. In an aspect, the received component 112 may include one or more state register values. In an aspect, prediction engine 118 may compare received component 112 (e.g., V(k)) and a lower bound value (b(k)) at time (t) and if any V(k) is within a tolerance (tol) of b(k), then prediction engine 118 may determine that a supply voltage control signal value 132 for time (t) equals “1” (e.g., the control signal 132 prompts PA switcher 140 to use a path with a voltage supply). By contrast, where V(k) at time t does not fall within the tolerance for any b(k) value, then a supply voltage control signal value 132 for time (t) may equal “0” (e.g., the control signal 132 prompts PA switcher 140 to use a path with a voltage ground). Further, in operation, the control signal 132 may pass through a delay match 126 (e.g., buffer) so as to match the arrival of the analog signal from RTR 126 at the PA 148 with the smoothed supply voltage 116 from the low pass filter 146. In an aspect, a state register may be updated for a time (t) plus a time increment (dt) and the prediction engine 118 may estimate a voltage (Ve) value 120 for a future time (V(k)=V(k+1)−h(k), Vd=V(1) when Vs(t)=0, and V(k)=V(k+1)−h(k)+h(k+1), Vd=V(1)+h(1) when Vs(t)=1).

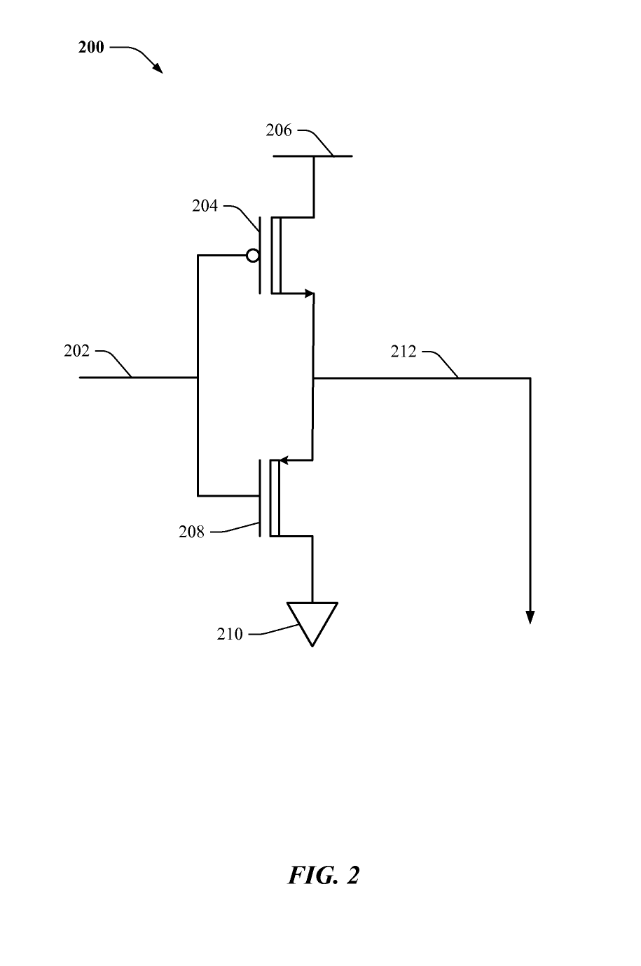

FIG. 2 illustrates an example schematic diagram of a processor controlled power amplifier (PA) switcher 200. PA switcher 200 may include a switcher control line 202 from a processor (e.g., modem, RF chip, etc.), a first gate 204 coupled to a power supply 206, a second gate 206 coupled to a voltage ground 210, and a voltage supply line 212 that is coupled to the power amplifier.

In operation, PA switcher 200 may receive a control signal from a processor over switcher control line 202. In an aspect, the control signal may be a binary signal where “0” indicates that a battery voltage supply path should be used, and “1” indicates that a ground voltage path should be used, or vise versa. In such an aspect, depending of the content of the control signal, either the first fate 204 or the second gate 208 is used. Where the control signal indicates that the supply voltage to the power amplifier is to be provided from a battery power supply 206, then the first gate 204 is active. Where the control signal indicates that the supply voltage to the power amplifier is to be provided from a voltage ground 210, then the second gate 210 is active. As such, PA switcher 200 may provide a supply voltage over the voltage supply line 212 to a low pass filter to be processed and used by a power amplifier. In such an aspect, the processor may determine the control signal based on a future characteristics of the input signal.

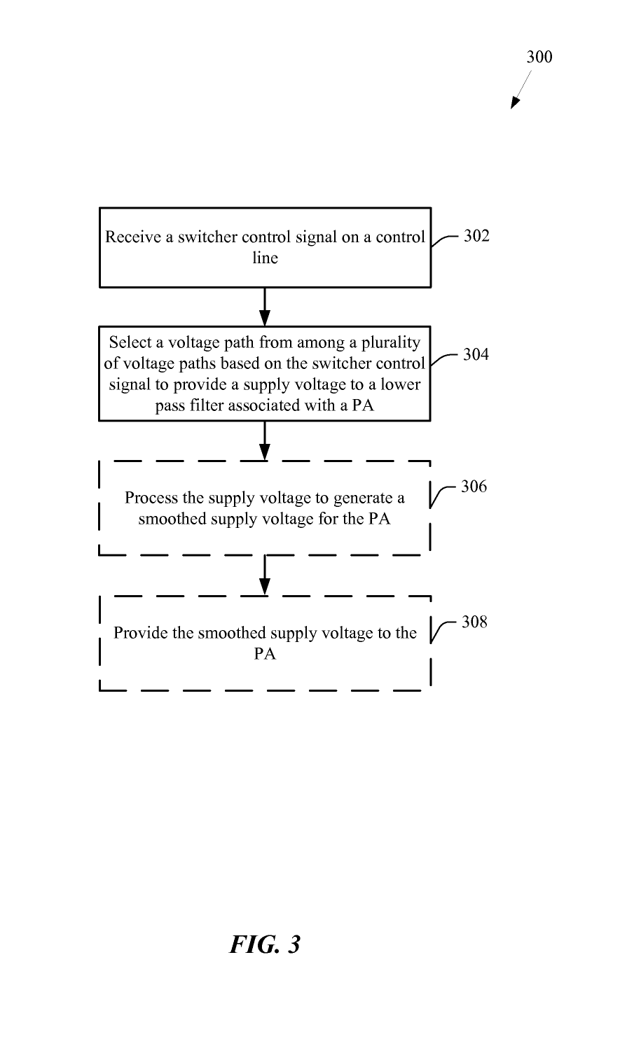

FIG. 3 illustrates methodologies in accordance with various aspects of the presented subject matter. While the methodologies are shown and described as a series of acts or sequence steps for the purposes of simplicity of explanation, it is to be understood and appreciated that the claimed subject matter is not limited by the order of acts, as some acts may occur in different orders and/or concurrently with other acts from that shown and described herein. For example, those skilled in the art will understand and appreciate that a methodology could alternatively be represented as a series of interrelated states or events, such as in a state diagram. Moreover, not all illustrated acts may be required to implement a methodology in accordance with the claimed subject matter. Additionally, it should be further appreciated that the methodologies disclosed hereinafter and throughout this specification are capable of being stored on an article of manufacture to facilitate transporting and transferring such methodologies to computers. The term article of manufacture, as used herein, is intended to encompass a computer program accessible from any computer-readable device, carrier, or media.

FIG. 3 illustrates a flowchart 300 describing a method for controlling a switcher to provide a supply voltage to a high efficiency power supply via a low pass filter.

At block 302, a switcher may a switcher control signal on a control line. In an aspect, the switcher control signal may be generated by a processor and based on future characteristics of an input signal. In an aspect, the control line may be a 1-bit control line. In another aspect, the control line may be a multi-bit control line and may include switch instructions for one or more components, such as but not limited to, one or more PAs, one or more states within a PA, or one or more capacitors in a low pass filter.

At block 304, the switcher may select a voltage path from among a plurality of voltage paths based on the switcher control signal to provide a supply voltage to a low pass filter associated with a power amplifier (PA). In an aspect, the plurality of voltage paths may include a source voltage path and a ground voltage path. In such an aspect, the control signal may be a binary signal where “0” indicates that a source (e.g., battery) voltage supply path should be used, and “1” indicates that a ground voltage path should be used, or vise versa. In one aspect, the switch control signal indicates which path to use based on future characteristics of a buffered input signal. In such an aspect, the future characteristics may be based on a system response associated with the input signal. In other words, the switcher path decision may be made by a processor (e.g., modem, RF chip, etc.).

In an optional aspect, the supply voltage generated through the switcher, based on the received switcher control signal, at block 306, may be processed through a low pass filter to generate a smoothed supply voltage. In such an optional aspect, at block 308, the smoothed supply voltage may be provided to the PA.

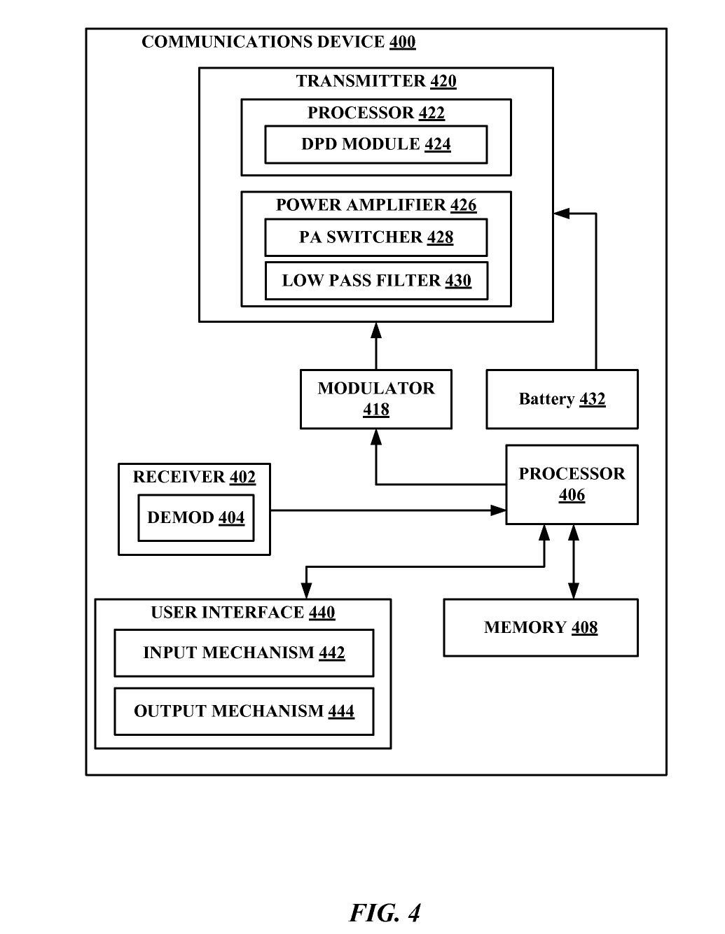

FIG. 4 illustrates an example architecture of communications device 400. As depicted in FIG. 4, communications device 400 includes receiver 402 that receives a signal from, for instance, a receive antenna (not shown), performs typical actions on (e.g., filters, amplifies, downconverts, etc.) the received signal, and digitizes the conditioned signal to obtain samples. Receiver 402 can include a demodulator 404 that can demodulate received symbols and provide them to processor 406 for channel estimation. Processor 406 can be a processor dedicated to analyzing information received by receiver 402 and/or generating information for transmission by transmitter 420, a processor that controls one or more components of communications device 400, and/or a processor that both analyzes information received by receiver 402, generates information for transmission by transmitter 420, and controls one or more components of communications device 400. Further, signals may be prepared for transmission by transmitter 420 through modulator 418 which may modulate the signals processed by processor 406.

Communications device 400 can additionally include memory 408 that is operatively coupled to processor 406 and that can store data to be transmitted, received data, information related to available channels, TCP flows, data associated with analyzed signal and/or interference strength, information related to an assigned channel, power, rate, or the like, and any other suitable information for estimating a channel and communicating via the channel. Communications device 400 can additionally include a power supply (e.g., battery 432, power supply interface, etc.).

Further, at least one of processor 406 or transmitter 420 can provide means for receiving, by a PA switcher 428, a switcher control signal on a control line, and means for selecting a voltage path from among a plurality of voltage paths based on the switcher control signal to provide a supply voltage to a lower pass filter 430 associated with a PA 426.

It will be appreciated that data store (e.g., memory 408) described herein can be either volatile memory or nonvolatile memory, or can include both volatile and nonvolatile memory. By way of illustration, and not limitation, nonvolatile memory can include read only memory (ROM), programmable ROM (PROM), electrically programmable ROM (EPROM), electrically erasable PROM (EEPROM), or flash memory. Volatile memory can include random access memory (RAM), which acts as external cache memory. By way of illustration and not limitation, RAM is available in many forms such as synchronous RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), and direct Rambus RAM (DRRAM). Memory 408 of the subject systems and methods may comprise, without being limited to, these and any other suitable types of memory.

Communications device 400 transmitter 420 may include processor 422 and power amplifier 426. In an aspect, processor 422 may include a digital predistortion (DPD) module 424 that may be configured apply a DPD to an input signal that is to be transmitted using power amplifier 426 so as to account for distortion resulting from power amplification. Power amplifier 426 may include a PA switcher 428 and a low pass filter 430. In an aspect, processor 422 may supply a control signal to PA switcher 428 to prompt PA switcher 428 to select among a plurality of possible voltage paths to generate a supply voltage for power amplifier 426. In an aspect, the various possible voltage paths may include a ground path, a voltage supply (e.g., batter 432) path, etc. The supply voltage may be provided to low pass filter 430 to generate a smoothed supply voltage for use during power amplification by power amplifier 426. Further description of interactions between processor 422 and power amplifier 426 are provided above with reference to FIGS. 1 and 2.

Additionally, communications device 400 may include user interface 440. User interface 440 may include input mechanisms 442 for generating inputs into communications device 400, and output mechanism 444 for generating information for consumption by the user of the communications device 400. For example, input mechanism 442 may include a mechanism such as a key or keyboard, a mouse, a touch-screen display, a microphone, etc. Further, for example, output mechanism 444 may include a display, an audio speaker, a haptic feedback mechanism, etc. In the illustrated aspects, the output mechanism 444 may include a display configured to present media content that is in image or video format or an audio speaker to present media content that is in an audio format.

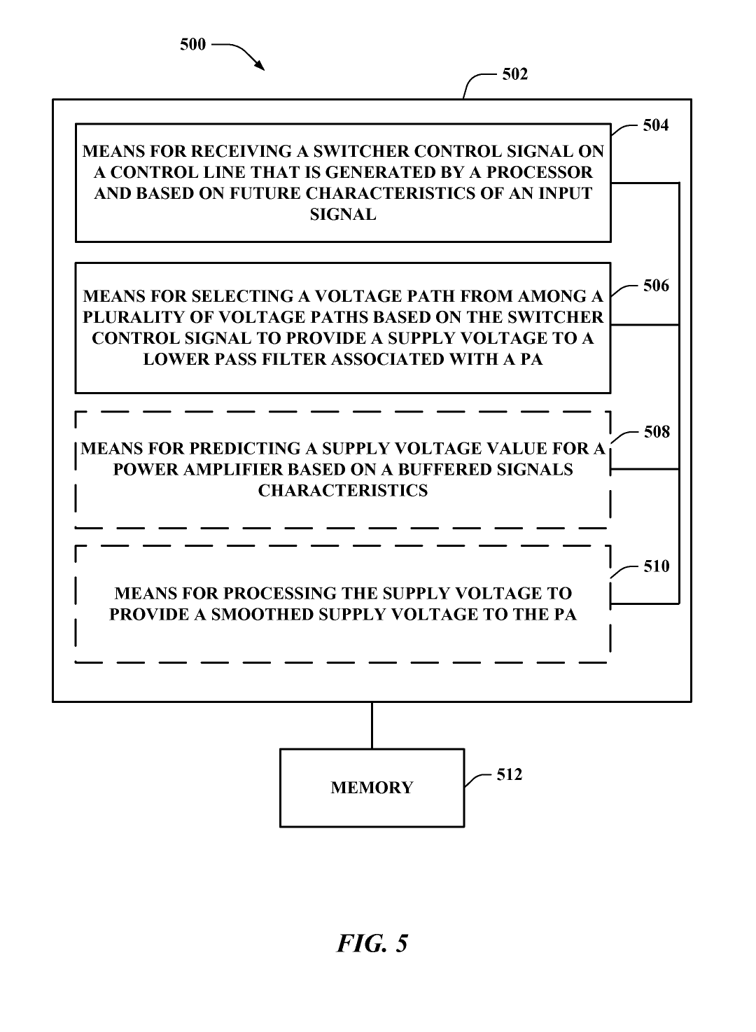

Referring to FIG. 5, an apparatus 500 that use a processor controlled switcher architecture with a high-efficiency power amplifier can reside at least partially within a transmitter. It is to be appreciated that apparatus 500 is represented as including functional blocks, which can represent functions implemented by a processor, software, or combination thereof (e.g., firmware).

As such, apparatus 500 includes a logical grouping 502 of electrical components that can act in conjunction. For instance, logical grouping 502 can include means for means for receiving a switcher control signal on a control line (Block 504). In an aspect, the switcher control signal may be generated by a processor and based on future characteristics of an input signal. In another aspect, the control line is a 1-bit control line. In another aspect, the control line may be a multi-bit control line and the switcher control signal includes switch instructions for components. In such an aspect, the components may include one or more PAs, one or more states within a PA, or one or more capacitors in a low pass filter. For example, in an aspect, the means 504 can include power amplifier 426 of communications device 400 and/or processor 406 of communications device 400.

Further, logical grouping 502 can include means for selecting a voltage path from among a plurality of voltage paths based on the switcher control signal to provide a supply voltage to a lower pass filter associated with a PA (Block 506). In an aspect, the plurality of voltage path may include one or more source voltage paths, a ground voltage path, etc. In another aspect, one source voltage path may be coupled to the battery 432. For example, in an aspect, the means for selecting 506 may include PA switcher 428 of communications device 400 and/or processor 406 of communications device 400.

In an optional aspect, logical grouping 502 can include means for predicting future characteristic of the buffered input signal based on a system response associated with the input signal (Block 508). For example, in an aspect, the means for predicting 508 can include processor 422 of communications device 400 and/or processor 406 of communications device 400. In an aspect, the means for predicting 508 may include means for generate the switcher control signal based on the predicted one or more future characteristic of the input signal, and means for providing the switcher control signal for the switcher. In an aspect, the predicted supply voltage may be based on a predicted output matching for the input signal. In another aspect, the predicted supply voltage may be based on a minimization of the supply voltage to the power amplifier.

In another optional aspect, logical grouping 502 can include means for generating a smoothed supply voltage from the supply voltage. For example, in an aspect, the means for generating 508 can include low pass filter 430 of communications device 400 and/or processor 406 of communications device 400. In such an aspect, the smoothed supply voltage may be provided to the PA. In an aspect, the means for generating 508 may include means for receiving a supply voltage from a switcher, means for processing the supply voltage to generate a smoothed supply voltage for the PA, and means for providing the smoothed supply voltage to the PA.

Additionally, apparatus 500 can include a memory 512 that retains instructions for executing functions associated with electrical components 504, 506, 508, and 510. While shown as being external to memory 512, it is to be understood that one or more of electrical components 504, 506, 508, and 510 can exist within memory 512. In an aspect, for example, memory 512 may be the same as or similar to memory 408 (FIG. 4).

As used in this application, the terms “component,” “module,” “system” and the like are intended to include a computer-related entity, such as but not limited to hardware, firmware, a combination of hardware and software, software, or software in execution. For example, a component may be, but is not limited to being, a process running on a processor, a processor, an object, an executable, a thread of execution, a program, and/or a computer. By way of illustration, both an application running on a computing device and the computing device can be a component. One or more components can reside within a process and/or thread of execution and a component may be localized on one computer and/or distributed between two or more computers. In addition, these components can execute from various computer readable media having various data structures stored thereon. The components may communicate by way of local and/or remote processes such as in accordance with a signal having one or more data packets, such as data from one component interacting with another component in a local system, distributed system, and/or across a network such as the Internet with other systems by way of the signal.

Furthermore, various aspects are described herein in connection with a terminal, which can be a wired terminal or a wireless terminal. A terminal can also be called a system, device, subscriber unit, subscriber station, mobile station, mobile, mobile device, remote station, remote terminal, access terminal, user terminal, terminal, communication device, user agent, user device, or user equipment (UE). A wireless terminal may be a cellular telephone, a satellite phone, a cordless telephone, a Session Initiation Protocol (SIP) phone, a wireless local loop (WLL) station, a personal digital assistant (PDA), a handheld device having wireless connection capability, a computing device, or other processing devices connected to a wireless modem. Moreover, various aspects are described herein in connection with a base station. A base station may be utilized for communicating with wireless terminal(s) and may also be referred to as an access point, a Node B, or some other terminology.

Moreover, the term “or” is intended to mean an inclusive “or” rather than an exclusive “or.” That is, unless specified otherwise, or clear from the context, the phrase “X employs A or B” is intended to mean any of the natural inclusive permutations. That is, the phrase “X employs A or B” is satisfied by any of the following instances: X employs A; X employs B; or X employs both A and B. In addition, the articles “a” and “an” as used in this application and the appended claims should generally be construed to mean “one or more” unless specified otherwise or clear from the context to be directed to a singular form.

The techniques described herein may be used for various wireless communication systems such as CDMA, TDMA, FDMA, OFDMA, SC-FDMA and other systems. The terms “system” and “network” are often used interchangeably. A CDMA system may implement a radio technology such as Universal Terrestrial Radio Access (UTRA), cdma2000, etc. UTRA includes Wideband-CDMA (W-CDMA) and other variants of CDMA. Further, cdma2000 covers IS-2000, IS-95 and IS-856 standards. A TDMA system may implement a radio technology such as Global System for Mobile Communications (GSM). An OFDMA system may implement a radio technology such as Evolved UTRA (E-UTRA), Ultra Mobile Broadband (UMB), IEEE 802.11 (Wi-Fi), IEEE 802.16 (WiMAX), IEEE 802.20, Flash-OFDM, etc. UTRA and E-UTRA are part of Universal Mobile Telecommunication System (UMTS). 3GPP Long Term Evolution (LTE) is a release of UMTS that uses E-UTRA, which employs OFDMA on the downlink and SC-FDMA on the uplink. UTRA, E-UTRA, UMTS, LTE and GSM are described in documents from an organization named “3rd Generation Partnership Project” (3GPP). Additionally, cdma2000 and UMB are described in documents from an organization named “3rd Generation Partnership Project 2” (3GPP2). Further, such wireless communication systems may additionally include peer-to-peer (e.g., mobile-to-mobile) ad hoc network systems often using unpaired unlicensed spectrums, 802.xx wireless LAN, BLUETOOTH and any other short- or long-range, wireless communication techniques.

Various aspects or features will be presented in terms of systems that may include a number of devices, components, modules, and the like. It is to be understood and appreciated that the various systems may include additional devices, components, modules, etc. and/or may not include all of the devices, components, modules etc. discussed in connection with the figures. A combination of these approaches may also be used.

The various illustrative logics, logical blocks, modules, and circuits described in connection with the embodiments disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but, in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. Additionally, at least one processor may comprise one or more modules operable to perform one or more of the steps and/or actions described above.

Further, the steps and/or actions of a method or algorithm described in connection with the aspects disclosed herein may be embodied directly in hardware, in a software module executed by a processor, or in a combination of the two. A software module may reside in RAM memory, flash memory, ROM memory, EPROM memory, EEPROM memory, registers, a hard disk, a removable disk, a CD-ROM, or any other form of storage medium known in the art. An exemplary storage medium may be coupled to the processor, such that the processor can read information from, and write information to, the storage medium. In the alternative, the storage medium may be integral to the processor. Further, in some aspects, the processor and the storage medium may reside in an ASIC. Additionally, the ASIC may reside in a user terminal. In the alternative, the processor and the storage medium may reside as discrete components in a user terminal. Additionally, in some aspects, the steps and/or actions of a method or algorithm may reside as one or any combination or set of codes and/or instructions on a machine readable medium and/or computer readable medium, which may be incorporated into a computer program product.

In one or more aspects, the functions described may be implemented in hardware, software, firmware, or any combination thereof. If implemented in software, the functions may be stored or transmitted as one or more instructions or code on a computer-readable medium. Computer-readable media includes both computer storage media and communication media including any medium that facilitates transfer of a computer program from one place to another. A storage medium may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection may be termed a computer-readable medium. For example, if software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs usually reproduce data optically with lasers. Combinations of the above should also be included within the scope of computer-readable media.

While the foregoing disclosure discusses illustrative aspects and/or embodiments, it should be noted that various changes and modifications could be made herein without departing from the scope of the described aspects and/or embodiments as defined by the appended claims. Furthermore, although elements of the described aspects and/or embodiments may be described or claimed in the singular, the plural is contemplated unless limitation to the singular is explicitly stated. Additionally, all or a portion of any aspect and/or embodiment may be utilized with all or a portion of any other aspect and/or embodiment, unless stated otherwise.

What is claimed is:

1. A method of communications, comprising:
receiving a switcher control signal on a control line, wherein the switcher control signal is generated by a processor and based on future characteristics of an input signal; and
selecting, by a switcher, a voltage path from among a plurality of voltage paths based on the switcher control signal to provide a supply voltage to a low pass filter associated with a power amplifier (PA).

2. The method of claim 1, further comprising:
providing the supply voltage to the low pass filter;
processing, by the low pass filter, the supply voltage to generate a smoothed supply voltage for the PA; and
providing the smoothed supply voltage to the PA.

3. The method of claim 1, wherein the plurality of voltage paths include a source voltage path and a ground voltage path.

4. The method of claim 1, wherein the control line is a 1-bit control line.

5. The method of claim 1, wherein processor comprises at least one of a modem or a radio frequency (RF) chip.

6. The method of claim 1, wherein the control line is a multi-bit control line and the switcher control signal includes switch instructions for one or more components.

7. The method of claim 6, wherein the one or more components comprise at least one of: one or more PAs, one or more states within a PA, or one or more capacitors in a low pass filter.

8. The method of claim 1, wherein the processor is a modem, and wherein the future characteristics are determined by the modem based on a system response associated with the input signal that is stored in a buffer.

9. The method of claim 1, wherein the switcher control signal is generated to minimize a supply voltage used by the PA to transmit the input signal.

10. An apparatus, comprising:
a switcher including a control line, a plurality of voltage paths, and a supply line to a low pass filter associated with a power amplifier (PA), wherein the switcher is configured to:
receive a switcher control signal on the control line, wherein the switcher control signal is based on one or more future characteristics of an input signal; and
select a voltage path from among a plurality of voltage paths based on the switcher control signal to provide a supply voltage to the lower pass filter associated with the PA.

11. The apparatus of claim 10, wherein the low pass filter is configured to:
receive the supply voltage from the switcher;
process the supply voltage to generate a smoothed supply voltage for the PA; and
provide the smoothed supply voltage to the PA.

12. The apparatus of claim 10, wherein the control line is a 1-bit control line.

13. The apparatus of claim 10, wherein the control line is a multi-bit control line and the switcher control signal includes switch instructions for one or more components.

14. The apparatus of claim 13, wherein the one or more components comprise at least one of: one or more PA, one or more states within a PA, or one or more capacitors in a low pass filter.

15. The apparatus of claim 10, further comprising:
a buffer configured to store at least a portion of the input signal;
a processor, associated with the buffer, wherein the processor is configured to:
predict the one or more future characteristic of the buffered input signal based on a system response associated with the input signal;
generate the switcher control signal based on the predicted one or more future characteristic of the input signal; and
provide the switcher control signal for the switcher.

16. The apparatus of claim 15, wherein processor comprises at least one of a modem or a radio frequency (RF) chip.

17. The apparatus of claim 15, wherein the processor is further configured to generate the switch control signal to minimize a supply voltage used by the PA to transmit the input signal.

18. An apparatus for communications, comprising:
means for receiving a switcher control signal on a control line, wherein the switcher control signal is generated by a processor and based on future characteristics of an input signal; and
means for selecting a voltage path from among a plurality of voltage paths based on the switcher control signal to provide a supply voltage to a lower pass filter associated with a power amplifier (PA).

19. The apparatus of claim 18, further comprising means for generating a smoothed supply voltage from the supply voltage, wherein the smoothed supply voltage is provided to the PA.

20. The apparatus of claim 18, wherein the plurality of voltage path include a source voltage path and a ground voltage path.

21. The apparatus of claim 18, wherein the control line is a 1-bit control line.

22. The apparatus of claim 18, wherein the processor comprises at least one of a modem or a radio frequency (RF) chip.

23. The apparatus of claim 18, wherein the control line is a multi-bit control line and the switcher control signal includes switch instructions for one or more components.

24. The apparatus of claim 23, wherein the one or more components comprise at least one of: one or more PAs, one or more states within a PA, or one or more capacitors in a low pass filter.

25. The apparatus of claim 18, further comprising:
means for predicting the one or more future characteristic of the buffered input signal based on a system response associated with the input signal; and
means for generating the switcher control signal based on the predicted one or more future characteristic of the input signal.

26. The apparatus of claim 18, wherein the switcher control signal is generated to minimize a supply voltage used by the PA to transmit the input signal.

27. A computer program product, comprising:
a computer-readable medium comprising code for:
receiving a switcher control signal on a control line, wherein the switcher control signal is generated by a processor and based on future characteristics of an input signal; and
selecting a voltage path from among a plurality of voltage paths based on the switcher control signal to provide a supply voltage to a lower pass filter associated with a power amplifier (PA).
